(19) United States
(12) Patent Application Publication
(10) Pub. No.: US 2019/0253663 A1
(43) Pub. Date: Aug. 15, 2019

(54) CABLE TELEVISION APPARATUS USING COUPLED-LINE DIRECTIONAL COUPLER IMPLEMENTING HIGH PASS FILTER FUNCTION

(71) Applicant: CABLE VISION ELECTRONICS CO., LTD, New Taipei City (TW)

(72) Inventors: Chien-Chung LEE, New Taipei City (TW); Ching-Po YANG, New Taipei City (TW); Wen-Ray YU, New Taipei City (TW)

(21) Appl. No.: 15/922,261

(22) Filed: Mar. 15, 2018

(30) Foreign Application Priority Data
Feb. 13, 2018 (TW) 107202300

(51) Int. Cl. H01P 5/18; H04N 7/10; H03F 3/189; H03F 3/60; H03H 7/01

(52) U.S. Cl. CPC H04N 7/104; H01P 5/185; H01P 5/187; H01B 11/1895; H03F 3/189; H03F 3/60; H03H 7/0153; H01P 5/183

(57) ABSTRACT

A cable television apparatus includes a coupled-line directional coupler. The coupled-line directional coupler includes a coupled-line directional coupler body, an input side, an output side and a coupled side. The coupled-line directional coupler body receives a cable television video-audio-data signal through the input side or the output side. The coupled-line directional coupler body receives a high frequency signal through the input side. A frequency of the high frequency signal is higher than a frequency of the cable television video-audio-data signal. The coupled-line directional coupler body electromagnetically couples the high frequency signal to the coupled side. The coupled-line directional coupler includes a high pass filter function at the coupled side to filter out the cable television video-audio-data signal.

### BACKGROUND OF THE INVENTION

### Field of the Invention

The present invention relates to a cable television apparatus, and especially relates to a cable television apparatus using a coupled-line directional coupler implementing a high pass filter function.

### Description of the Related Art

Currently, the cable television system is very popular. The cable television system transmits television programs and network signals to client sides through coaxial cables. The client sides can use multimedia over coax alliance (which is usually abbreviated as MoCA) apparatuses so that a plurality of rooms have the network signals to use at the same time.

The related art cable television system needs to use the directional coupler to transmit the television programs and the network signals. However, the related art directional coupler has the high insertion loss and the bad isolation at the higher frequency applications (for example, MoCA applications), so that the quality of signals with the higher frequency (for example, MoCA signals) is influenced. Moreover, in order to filter out the signal with the lower frequency, for example the cable television video-audio-data signal, the related art directional coupler needs to work with a high pass filter (which comprises inductors and capacitors) and core windings which belong to the related art directional coupler itself, so that the cost of the inductors, the capacitors and the core windings increases.

### SUMMARY OF THE INVENTION

In order to solve the above-mentioned problems, an object of the present invention is to provide a cable television apparatus using a coupled-line directional coupler implementing a high pass filter function.

In order to achieve the object of the present invention mentioned above, the cable television apparatus of the present invention includes a coupled-line directional coupler. Moreover, the coupled-line directional coupler includes a coupled-line directional coupler body, an input side, an output side and a coupled side. The input side is electrically connected to the coupled-line directional coupler body. The output side is electrically connected to the coupled-line directional coupler body and the input side. The coupled side is electrically connected to the coupled-line directional coupler body. Moreover, the coupled-line directional coupler body is configured to receive a cable television video-audio-data signal through the input side or the output side. The coupled-line directional coupler body is configured to receive a high frequency signal through the input side. A frequency of the high frequency signal is higher than a frequency of the cable television video-audio-data signal. The coupled-line directional coupler body is configured to electromagnetically couple the high frequency signal to the coupled side. The coupled-line directional coupler is configured to comprise a high pass filter function at the coupled side to filter out the cable television video-audio-data signal.

Moreover, in the cable television apparatus mentioned above, the high frequency signal is a multimedia over coax alliance signal.

Moreover, in the cable television apparatus mentioned above, the coupled-line directional coupler body is configured to receive a back-end signal through the coupled side. The coupled-line directional coupler body is configured to electromagnetically couple the back-end signal to the input side.

Moreover, the cable television apparatus mentioned above further comprises a housing. The coupled-line directional coupler is arranged inside the housing.

Moreover, the cable television apparatus mentioned above further comprises a cable television back-end circuit electrically connected to the coupled side.

Moreover, in the cable television apparatus mentioned above, the cable television back-end circuit comprises a splitter sub circuit electrically connected to the coupled side.

Moreover, in the cable television apparatus mentioned above, the cable television back-end circuit further comprises a cable television port sub circuit electrically connected to the splitter sub circuit.

Moreover, in the cable television apparatus mentioned above, the coupled-line directional coupler further comprises an isolation side electrically connected to the coupled-line directional coupler body and the coupled side.

Moreover, in the cable television apparatus mentioned above, the coupled-line directional coupler further comprises a resistor electrically connected to the isolation side.

Moreover, in the cable television apparatus mentioned above, the coupled-line directional coupler body comprises a first path and a second path. The first path is connected between the isolation side and the coupled side. The second path is connected between the input side and the output side.

Moreover, in the cable television apparatus mentioned above, the first path comprises a first segment, a first jumper wire group and a second segment. The first segment is connected to the isolation side. The first jumper wire group is connected to the first segment. The second segment is connected between the first jumper wire group and the coupled side. The second path comprises a third segment, a second jumper wire group and a fourth segment. The third segment is connected to the output side. The second jumper wire group is connected to the third segment.

The fourth segment is connected between the second jumper wire group and the input side.

The advantage of the present invention is to reduce the insertion loss of the directional coupler applied to the cable television field at the higher frequency, and to increase the isolation of the directional coupler. Moreover, the coupled-line directional coupler is manufactured only by the printed circuit board layout, so that the cost of the inductors, the capacitors and the core windings is saved.

Please refer to the detailed descriptions and figures of the present invention mentioned below for further understanding the technology, method and effect of the present invention. The figures are only for references and descriptions, and the present invention is not limited by the figures.

### BRIEF DESCRIPTION OF DRAWING

FIG. 1 shows a block diagram of a first embodiment of the cable television apparatus of the present invention.

FIG. 2 shows a block diagram of a second embodiment of the cable television apparatus of the present invention.

FIG. 3 shows a diagram that describes functions of the coupled-line directional coupler of the present invention.

FIG. 4 shows a layout diagram of an embodiment of the coupled-line directional coupler of the present invention.

### DETAILED DESCRIPTION OF THE INVENTION

In the present disclosure, numerous specific details are provided, to provide a thorough understanding of embodiments of the invention. Persons of ordinary skill in the art will recognize, however, that the present invention can be practiced without one or more of the specific details. In other instances, well-known details are not shown or described to avoid obscuring aspects of the present invention. Please refer to following detailed description and figures for the technical content of the present invention:

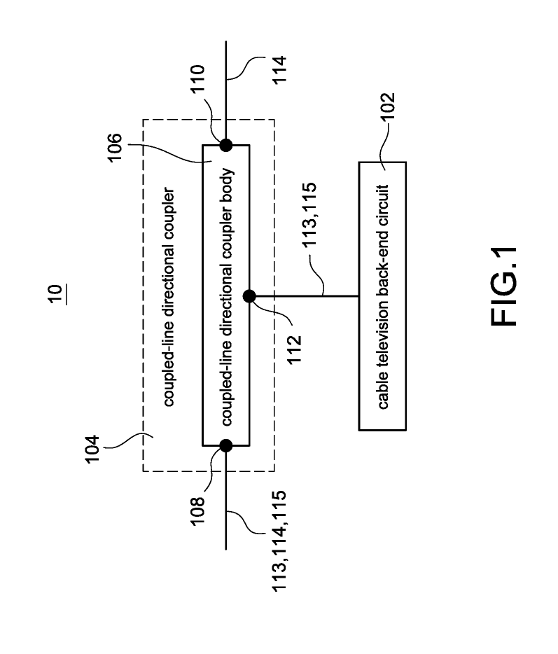

FIG. 1 shows a block diagram of a first embodiment of the cable television apparatus of the present invention. A cable television apparatus 10 comprises a cable television back-end circuit 102 and a coupled-line directional coupler 104. The coupled-line directional coupler 104 comprises a coupled-line directional coupler body 106, an input side 108, an output side 110 and a coupled side 112. The input side 108 is electrically connected to the coupled-line directional coupler body 106. The output side 110 is electrically connected to the coupled-line directional coupler body 106 and the input side 108. The coupled side 112 is electrically connected to the coupled-line directional coupler body 106. The cable television back-end circuit 102 is electrically connected to the coupled side 112.

The coupled-line directional coupler body 106 is configured to receive a cable television video-audio-data signal 114 through the input side 108 or the output side 110. The coupled-line directional coupler body 106 is configured to receive a high frequency signal 113 through the input side 108. A frequency of the high frequency signal 113 is higher than a frequency of the cable television video-audio-data signal 114. The coupled-line directional coupler body 106 is configured to electromagnetically couple the high frequency signal 113 to the coupled side 112. The coupled-line directional coupler 104 is configured to comprise a high pass filter function at the coupled side 112 to filter out the cable television video-audio-data signal 114. The high frequency signal 113 is a multimedia over coax alliance (which is usually abbreviated as MoCA) signal. The coupled-line directional coupler body 106 is configured to receive a back-end signal 115 through the coupled side 112. The coupled-line directional coupler body 106 is configured to electromagnetically couple the back-end signal 115 to the input side 108.

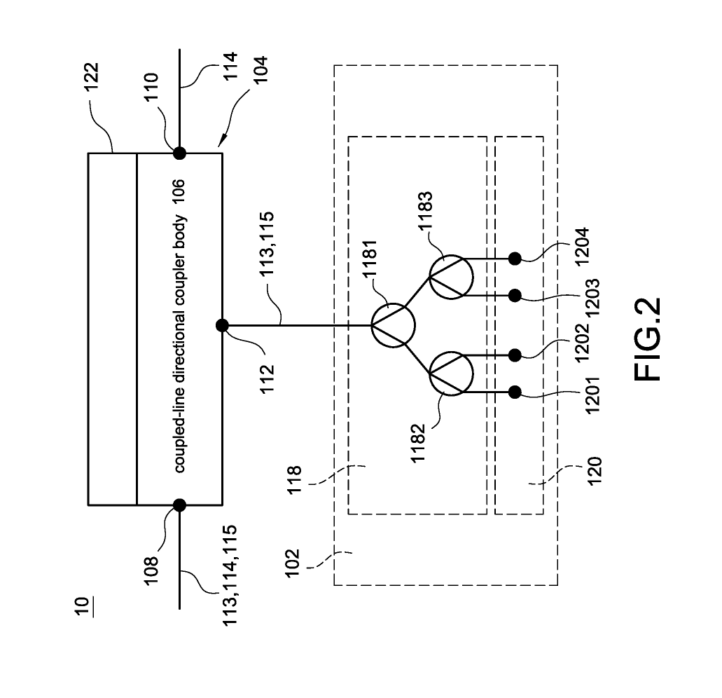

FIG. 2 shows a block diagram of a second embodiment of the cable television apparatus of the present invention. The descriptions of the elements shown in FIG. 2 which are the same as the elements shown in FIG. 1 are not repeated here for brevity. The cable television apparatus 10 further comprises a housing 122. The cable television back-end circuit 102 comprises a splitter sub circuit 118 and a cable television port sub circuit 120. The coupled-line directional coupler 104 is arranged inside the housing 122. The splitter sub circuit 118 is electrically connected to the coupled side 112. The cable television port sub circuit 120 is electrically connected to the splitter sub circuit 118.

Moreover, the splitter sub circuit 118 comprises a first splitter 1181, a second splitter 1182 and a third splitter 1183. The cable television port sub circuit 120 comprises a first cable television port 1201, a second cable television port 1202, a third cable television port 1203 and a fourth cable television port 1204. The first splitter 1181 is electrically connected to the coupled side 112. The second splitter 1182 is electrically connected to the first splitter 1181. The third splitter 1183 is electrically connected to the first splitter 1181. The first cable television port 1201 is electrically connected to the second splitter 1182. The second cable television port 1202 is electrically connected to the second splitter 1182. The third cable television port 1203 is electrically connected to the third splitter 1183. The fourth cable television port 1204 is electrically connected to the third splitter 1183.

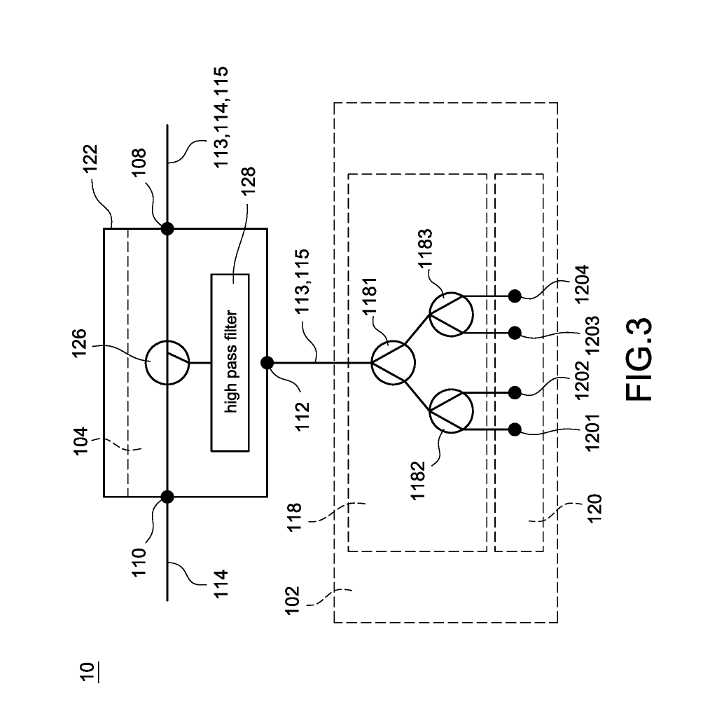

FIG. 3 shows a diagram that describes functions of the coupled-line directional coupler of the present invention. The descriptions of the elements shown in FIG. 3 which are the same as the elements shown in FIGS. 1-2 are not repeated here for brevity. The coupled-line directional coupler 104 comprises functions of a directional coupler 126 and functions of a high pass filter 128.

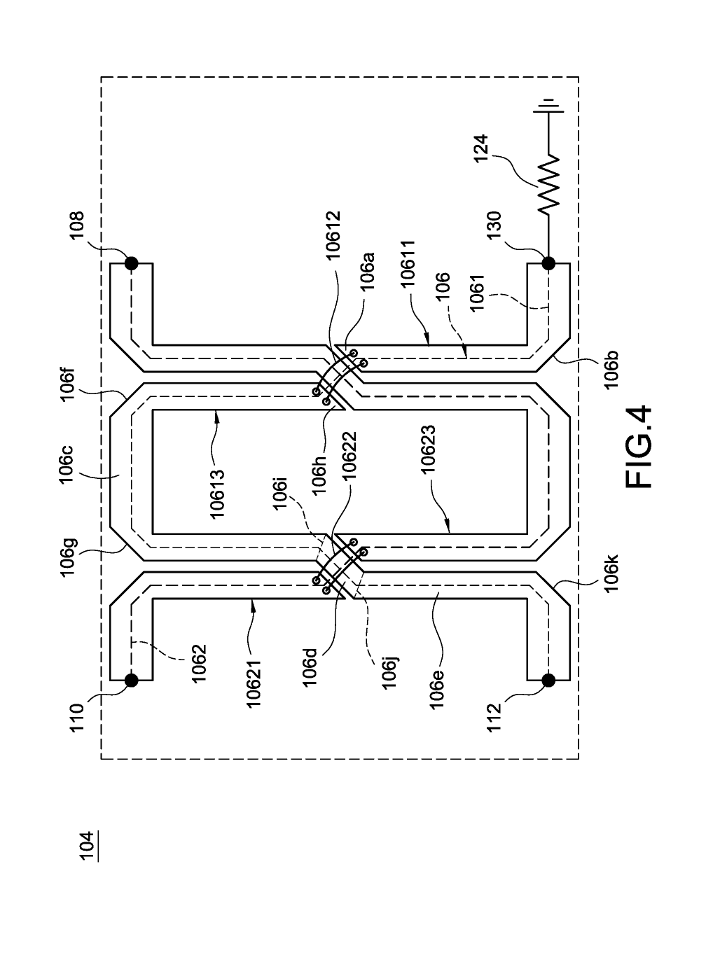

FIG. 4 shows a layout diagram of an embodiment of the coupled-line directional coupler of the present invention. The descriptions of the elements shown in FIG. 4 which are the same as the elements shown in FIGS. 1-3 are not repeated here for brevity. The coupled-line directional coupler 104 further comprises an isolation side 130 and a resistor 124. The coupled-line directional coupler body 106 comprises a first path 1061 and a second path 1062. The first path 1061 comprises a first segment 10611, a first jumper wire group 10612 and a second segment 10613. The second path 1062 comprises a third segment 10621, a second jumper wire group 10622 and a fourth segment 10623. The isolation side 130 is electrically connected to the coupled-line directional coupler body 106 and the coupled side 112. The resistor 124 is electrically connected to the isolation side 130. The first path 1061 is connected between the isolation side 130 and the coupled side 112. The second path 1062 is connected between the input side 108 and the output side 110. The first segment 10611 is connected to the isolation side 130. The first jumper wire group 10612 is connected to the first segment 10611. The second segment 10613 is connected between the first jumper wire group 10612 and the coupled side 112. The third segment 10621 is connected to the output side 110. The second jumper wire group 10622 is connected to the third segment 10621. The fourth segment 10623 is connected between the second jumper wire group 10622 and the input side 108.

Moreover, the first segment 10611 is L-shaped. A first upper side 106a of the first segment 10611 is beveled. The first upper side 106a is connected to the first jumper wire group 10612. A first vertical side 106b of the first segment 10611 is beveled. The second segment 10613 comprises an inverted-U-shaped segment 106c, a parallelogram connection segment 106d and an L-left-right-reversed segment 106e. An upper right side 106f of the inverted-U-shaped segment 106c is beveled. An upper left side 106g of the inverted-U-shaped segment 106c is beveled. A lower right side 106h of the inverted-U-shaped segment 106c is beveled. The lower right side 106h of the inverted-U-shaped segment 106c is connected to the first jumper wire group 10612. A lower left side 106i of the inverted-U-shaped segment 106c is beveled. The parallelogram connection segment 106d is connected to the lower left side 106i of the inverted-U-shaped segment 106c. A second upper side 106j of the L-left-right-reversed segment 106e is beveled. The second upper side 106j is connected to the parallelogram connection segment 106d. A second vertical side 106k of the L-left-right-reversed segment 106e is beveled. The third segment 10621 is the first segment 10611 rotated 180 degrees clockwise. The fourth segment 10623 is the second segment 10613 rotated 180 degrees clockwise. The first jumper wire group 10612 is across the fourth segment 10623. The second jumper wire group 10622 is across the parallelogram connection segment 106d.

Moreover, the present invention utilizes the microstrip technology that the layout of the directional coupler having the high pass filter function is layout/manufactured on the printed circuit board. Namely, the coupled-line directional coupler 104 is manufactured only by the printed circuit board layout to achieve the functions of the directional coupler and the high pass filter. The advantage of the present invention is to reduce the insertion loss of the directional coupler applied to the cable television field at the higher frequency, and to increase the isolation of the directional coupler. Moreover, the coupled-line directional coupler 104 is manufactured only by the printed circuit board layout, so that the cost of the inductors, the capacitors and the core windings is saved.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A cable television apparatus comprising:
a coupled-line directional coupler,
wherein the coupled-line directional coupler comprises:
a coupled-line directional coupler body;
an input side electrically connected to the coupled-line directional coupler body;
an output side electrically connected to the coupled-line directional coupler body and the input side; and
a coupled side electrically connected to the coupled-line directional coupler body,
wherein the coupled-line directional coupler body is configured to receive a cable television video-audio-data signal through the input side or the output side; the coupled-line directional coupler body is configured to receive a high frequency signal through the input side; a frequency of the high frequency signal is higher than a frequency of the cable television video-audio-data signal; the coupled-line directional coupler body is configured to electromagnetically couple the high frequency signal to the coupled side; the coupled-line directional coupler is configured to comprise a high pass filter function at the coupled side to filter out the cable television video-audio-data signal.

2. The cable television apparatus in claim 1, wherein the coupled-line directional coupler body is configured to receive a back-end signal through the coupled side; the coupled-line directional coupler body is configured to electromagnetically couple the back-end signal to the input side.

3. The cable television apparatus in claim 1, wherein the high frequency signal is a multimedia over coax alliance signal.

4. The cable television apparatus in claim 3 further comprising:
a housing,
wherein the coupled-line directional coupler is arranged inside the housing.

5. The cable television apparatus in claim 4 further comprising:
a cable television back-end circuit electrically connected to the coupled side.

6. The cable television apparatus in claim 5, wherein the cable television back-end circuit comprises a splitter sub circuit electrically connected to the coupled side.

7. The cable television apparatus in claim 6, wherein the cable television back-end circuit further comprises a cable television port sub circuit electrically connected to the splitter sub circuit.

8. The cable television apparatus in claim 1, wherein the coupled-line directional coupler further comprises an isolation side electrically connected to the coupled-line directional coupler body and the coupled side.

9. The cable television apparatus in claim 8, wherein the coupled-line directional coupler further comprises a resistor electrically connected to the isolation side.

10. The cable television apparatus in claim 9, wherein the coupled-line directional coupler body comprises:
a first path connected between the isolation side and the coupled side; and
a second path connected between the input side and the output side.

11. The cable television apparatus in claim 10, wherein the first path comprises:
a first segment connected to the isolation side;
a first jumper wire group connected to the first segment; and
a second segment connected between the first jumper wire group and the coupled side,
wherein the second path comprises:
a third segment connected to the output side;
a second jumper wire group connected to the third segment; and
a fourth segment connected between the second jumper wire group and the input side.
